(19) United States
(12) Patent Application Publication
(10) Pub. No.: US 2025/0102922 A1
(43) Pub. Date: Mar. 27, 2025

(54) Exposure method of semiconductor pattern

(71) Applicant: UNITED MICROELECTRONICS CORP., Hsin-Chu City (TW)

(72) Inventors: Shin-Hung Li, Nantou County (TW); Ruei-Jhe Tsao, New Taipei City (TW); Shan-Shi Huang, Hsinchu City (TW); Wen-Fang Lee, Hsinchu City (TW); Chiu-Te Lee, Hsinchu County (TW)

(73) Assignee: UNITED MICROELECTRONICS CORP., Hsin-Chu City (TW)

(21) Appl. No.: 18/382,528

(22) Filed: Oct. 22, 2023

(30) Foreign Application Priority Data
Sep. 25, 2023 (CN) 202311243129.0

(51) Int. Cl. G03F 7/00; H01L 21/027; H01L 21/033

(52) U.S. Cl. CPC G03F 7/70466; G03F 7/70283; H01L 21/0274; H01L 21/0337

(57) ABSTRACT

The invention provides an exposure method of semiconductor patterns, which comprises the following steps: providing a substrate, performing a first exposure step with a first photomask, forming a first pattern in a first region on the substrate, and performing a second exposure step with a second photomask, forming a second pattern in a second region on the substrate, the first pattern and the second pattern are in contact with each other, and at an interface of the first region And the second region, the first pattern and the second pattern are aligned with each other.

### BACKGROUND OF THE INVENTION

### 1. Field of the Invention

The invention relates to the field of semiconductor manufacturing, in particular to a method for forming a pattern on an ultra-large die.

### 2. Description of the Prior Art

With the progress of semiconductor manufacturing process, the size of semiconductor devices per unit area is getting smaller and smaller, and the density of devices is getting higher and higher. At the same time, the size of the die is gradually increased to accommodate more components. However, while increasing the die area, if the die area exceeds the limit value of the photomask range in the exposure step, it cannot to form patterns outside the exposure range, which will also limit the formation of components and hinder the development of large-scale die technology.

Therefore, there is a need for an exposure method of semiconductor patterns, which can solve the above problems.

### SUMMARY OF THE INVENTION

The invention provides an exposure method of semiconductor patterns, which comprises the following steps: providing a substrate, performing a first exposure step with a first photomask, forming a first pattern in a first region on the substrate, and performing a second exposure step with a second photomask, forming a second pattern in a second region on the substrate, wherein the first pattern and the second pattern are in contact with each other, and the first pattern and the second pattern are aligned with each other at an interface.

The invention is characterized in that a splicing pattern is formed on the super-large die by a double exposure method, so as to meet the component size requirements of the super-large die. The difference between the invention and the double exposure in the conventional step is that the formed patterns will be connected with each other and can be spliced into larger or longer patterns. Therefore, device patterns of various sizes can be simply formed on super-large dies without changing the existing process environment.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 3 are schematic diagrams showing the flow structure of a first preferred embodiment of the present invention, in which a top view of forming a pattern on a die is drawn.

FIG. 4 to FIG. 5 are schematic flow diagrams of a second preferred embodiment of the present invention, in which a top view of forming a pattern on a die is drawn.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

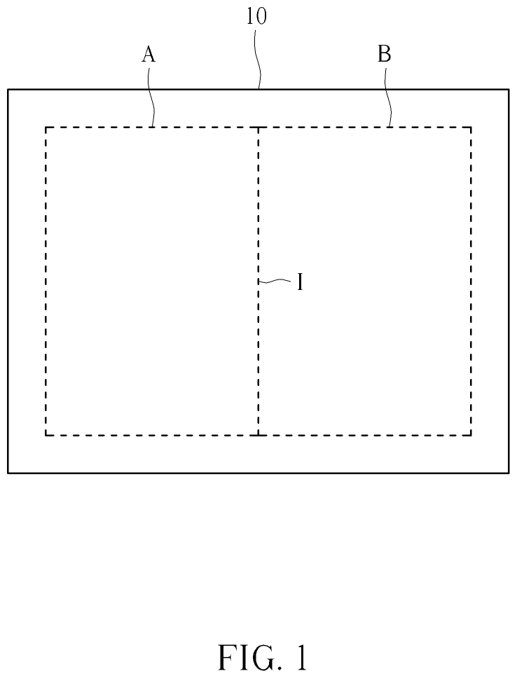

Please refer to FIGS. 1 to 3. FIGS. 1 to 3 show the schematic flow structure of a first preferred embodiment of the present invention, in which a top view of a die is drawn. First, as shown in FIG. 1, a die 10 is provided, on which a first region A and a second region B are arranged adjacent to each other, but the first region A and the second region B do not overlap each other. The die may be formed by a wafer through a dicing process. Generally speaking, the whole wafer is put into a semiconductor processing machine (such as an exposure and development machine or a deposition machine) and various required material layers are formed on the surface of the wafer before the wafer is cut into a plurality of dies. In the present invention, the pattern on a single die is emphasized. In order to clearly show the characteristics of the present invention, only a single die 10 is drawn in FIG. 1. However, it can be understood that the die in FIG. 1 may not have been cut, so it still belongs to a part of the wafer rather than an independent die.

Please continue to refer to FIG. 1. With the progress of the manufacturing process, more devices may be put into one die. For example, a display die needs to form a driving circuit and an array of light-emitting devices on the die, so the die with larger and larger size will be used. However, the size of the die may exceed the maximum area of a single area that can be exposed by the exposure machine, so the size of the pattern formed on the die is also limited. More specifically, the wafer contains a plurality of regions which are preferably arranged in an array, and each region is the die shown in FIG. 1 after being cut in the subsequent steps. When the exposure machine exposes the whole wafer, it will also perform the same exposure steps in each region. At this time, the area that the exposure machine can expose to a single region is usually called shot. When the size of the die is larger than the shot of the exposure machine, the required pattern cannot be formed on the die in a single exposure step.

Referring to the current process technology, taking FIG. 1 as an example, the shot area of the exposure machine used in FIG. 1 is about 26 mm*33 mm, which is equal to the size of the first region A and the second region B marked in FIG. 1. That is, the first region A and the second region B have the same area and are adjacent to each other. In addition, the area of the die 10 is preferably more than twice that of the first region A or the second region B. However, it is worth noting that the die 10 described in the present invention is different from, for example, a splicing substrate used for a display panel. Specifically, the area of the die 10 described in the present invention is only several times the area of a shot, while the area of the substrate used for splicing in a display panel is hundreds or thousands of times or more. Therefore, the ratio of the area of the die 10 to the shot area in the present invention is about 5 or less, and the ratio is preferably 2 to 3.

Therefore, taking the die 10 shown in FIG. 1 as an example, a single exposure step can only form the required pattern within the size range of the first region A or the second region B, but it is impossible to form the required pattern on the whole die 10 by one exposure step. Therefore, the present invention provides a method for forming a pattern, which forms a pattern spanning an area by splicing, so as to meet the requirements of a larger area of dies, as shown in the following paragraph in detail.

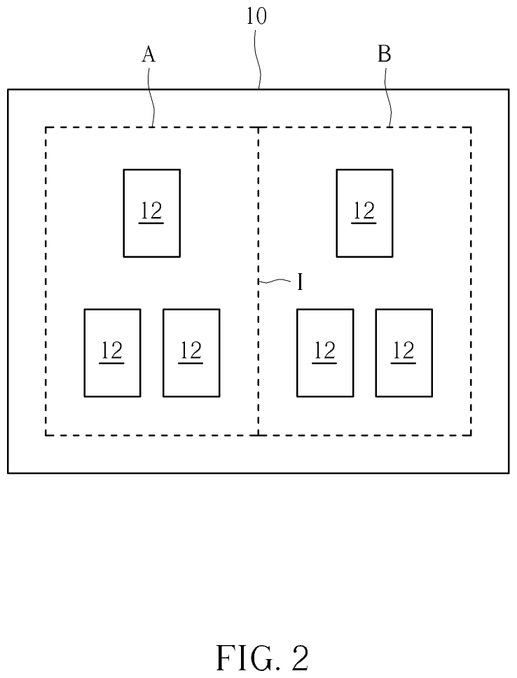

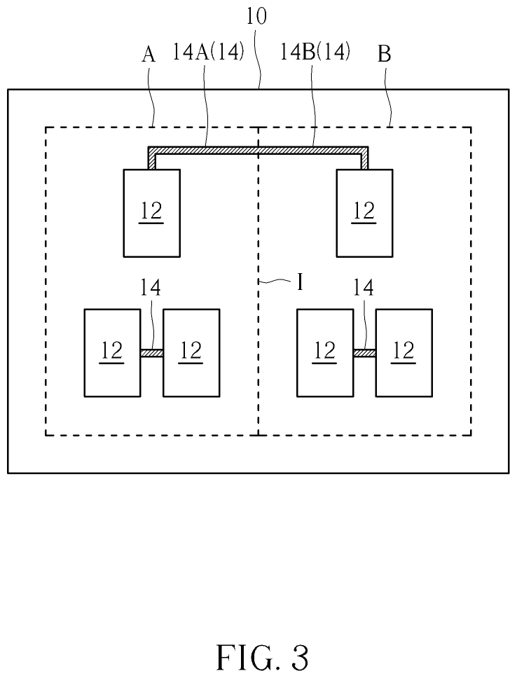

Please continue to refer to FIG. 2 and FIG. 3. In FIG. 2, the required device patterns 12 are respectively formed in the first region A and the second region B. The device patterns 12 described here are semiconductor structures such as transistors, resistors, capacitors, etc., but are not limited thereto. It is worth noting that in FIG. 2, the device patterns 12 required by the first region A and the second region B may be formed by separate processes such as exposure, development, etching and deposition. The above steps of exposure, development and deposition may include multiple steps and may be repeated. As mentioned above, since the size of the die 10 is larger than the single maximum exposure range (shot) of the exposure machine, it takes at least two exposures in total to form the device patterns contained in the first region A and the second region B.

As shown in FIG. 3, a conductor pattern is formed to connect part of the device patterns 12 with each other. One part of the conductor pattern 14 connects the respective device patterns 12 in the first region A or the second region B with each other, while the other part of the conductor patterns 14 connect with each other across the region. For example, the conductor patterns 14A and 14B in the first region A and the second region B indicated in FIG. 3 extend to the interface line I between the two regions respectively and contact and connect with each other. In this way, even if there are components with dimensions beyond the exposure range that need to be formed (for example, ultra-long conductor patterns), they can be completed by the method provided by the invention of performing two exposures and then splicing the patterns with each other.

In this embodiment, the conductor patterns 14A and 14B connected to adjacent regions are also aligned with each other. More specifically, the conductor pattern 14A has a first edge E1 and a second edge E2, while the conductor pattern 14B has a third edge E3 and a fourth edge E4, and the first edge E1 and the third edge E3 are aligned with each other in a first direction (for example, the horizontal direction, but not limited to this), while the second edge E2 and the fourth edge E4 are also aligned with each other in the first direction (for example, the horizontal direction, but not limited to this).

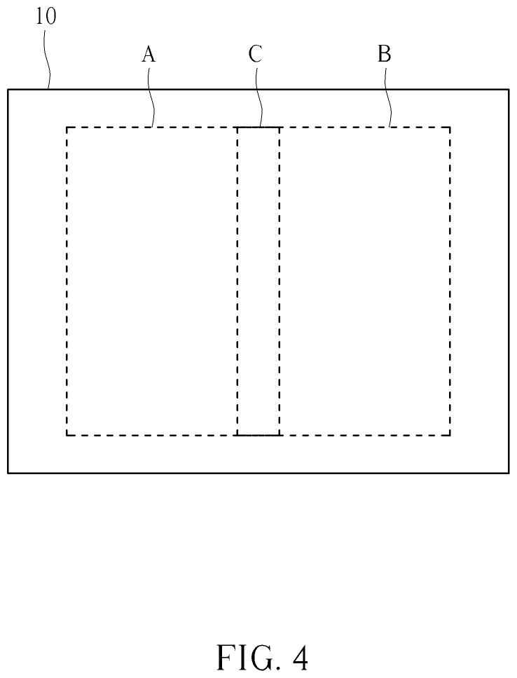

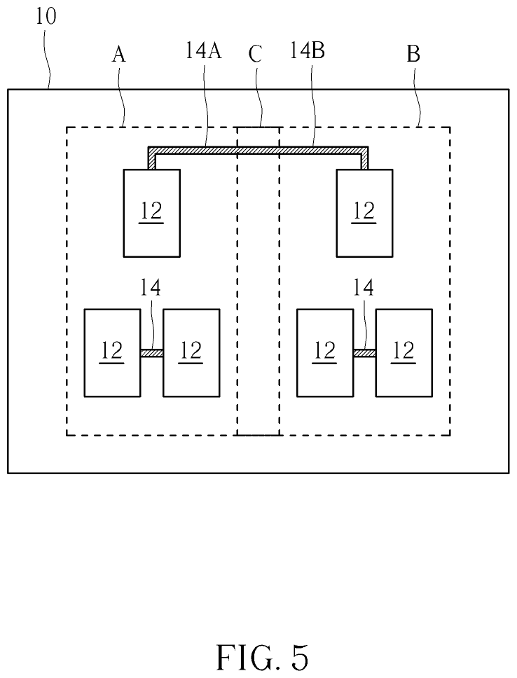

Please refer to FIGS. 4 to 5. FIGS. 4 to 5 show the schematic flow structure of the second preferred embodiment of the present invention, in which the top view of a die is drawn. This embodiment also provides a die 10, and the die 10 also includes a first region A and a second region B. The definitions of the die 10, the first region A and the second region B here are the same as those in the above embodiment, so they are not repeated here. The difference between this embodiment and the above embodiment lies in that the first region A and the second region B partially overlap with each other, which is defined as the region C in FIG. 4. The ratio of the area of the region C to the area of the first region A or the second region B is less than 20%, more preferably less than 10%, that is to say, only a few parts of the first region A and the second region B overlap each other, and most of the others do not.

Next, as shown in FIG. 5, after the required device patterns 12 are formed in the first region A and the second region B, the conductor patterns (including the conductor pattern 14, the conductor pattern 14A and the conductor pattern 14B) are formed. The conductor pattern 14A and the conductor pattern 14B are respectively formed in the first region A and the second region B, and they overlap each other in the region C. That is, the conductor pattern 14A and the conductor pattern 14B are connected to each other.

In this embodiment, because the first region A and the second region B partially overlap, the conductor pattern 14A and the conductor pattern 14B can be connected. Compared with the first embodiment, this embodiment can avoid the situation that the conductor pattern 14A and the conductor pattern 14B are not connected due to incomplete exposure near the interface line I.

In addition, it is worth noting that the applicant found that the line width of the conductor pattern in the region C may be slightly different from that of other conductor patterns not located in the region C because of the double exposure, and generally the line width of the pattern in the region C may be smaller than that in other regions. Therefore, preferably, in this embodiment, an optical proximity correction (OPC) step is performed before the two exposure steps, so as to adjust the line widths of the conductor patterns in different regions and improve the quality of the process.

In addition, it is worth noting that, although the conductor patterns 14A and 14B are used as elements crossing the region in the above embodiments, the present invention can also use other types of patterns besides conductors to cross the two regions. For example, the size of elements such as gate structures or fin structures may be longer than a single exposure shot, and it is also possible to form a pattern exceeding a single exposure shot by the method of two exposures and splicing provided by the present invention.

According to the invention, the patterns in the first region A and the second region B are respectively formed on the same die 10 by two exposure steps, and then the patterns that need to cross the two regions are spliced by a splicing method. Different from the double patterning used in the prior art, the double patterning technology in the prior art usually aims at reducing the pattern density of elements exposed once, so patterns are formed at different positions in the same region by two exposure steps. Please note that the area of the same region mentioned here is usually smaller than the single exposure range of the exposure machine (that is, the shot mentioned above). That is to say, in the conventional double patterning technology, the ranges of the two exposure processes are basically completely or mostly overlapped (more than 90% of the ranges are overlapped). However, in the present invention, the range of two exposure regions (i.e., the first region A and the second region B) may be only adjacent but not overlapped at all (as in the embodiment shown in FIG. 3), or only slightly overlapped (as in the embodiment shown in FIG. 5).

In addition, another difference between the present invention and the conventional double patterning technology is that the purpose of the conventional double patterning technology is to reduce the element density, so the formed device patterns usually do not touch each other to avoid mutual interference or short circuit, for example, a plurality of closely adjacent patterns (such as but not limited to patterns such as parallel wires or contact posts) are formed in the same region, and these patterns are preferably independent from each other without touching each other. The purpose of the invention is to splice patterns in different regions, so that a part of the finally formed patterns will cross the two regions and contact each other.

Based on the above description and drawings, the present invention provides an exposure method for semiconductor patterns, which includes providing a substrate (such as a wafer), performing a first exposure step with a first photomask, forming a first pattern (including the device pattern 12, the conductor pattern 14 and the conductor pattern 14A formed in the first region A, specifically the conductor pattern 14A here) in the first region A on the substrate, and performing a second exposure with a second photomask, so as to form a second pattern (including the device pattern 12, the conductor pattern 14 and the conductor pattern 14B, specifically the conductor pattern 14B here) in the second region B on the substrate, the first pattern 14A and the second pattern 14B are in contact with each other, and are aligned with each other at an interface line I.

In some embodiments of the present invention, there is further included a cutting step to cut the substrate into a plurality of dies 10, wherein the size of each die 10 is larger than an area of the first region A, and the first region A is equal to a single maximum exposure range (i.e., shot) of the first photomask.

In some embodiments of the present invention, the areas of the first region A and the second region B are equal, and the second region B is equal to a single maximum exposure range (i.e. shot) of the second photomask.

In some embodiments of the present invention, the area of the first region A is 26 mm*33 mm.

In some embodiments of the present invention, the size of each die 10 is larger than the area of the first region A.

In some embodiments of the present invention, the first pattern 14A includes a first edge E1 and a second edge E2, and the second pattern 14B includes a third edge E3 and a fourth edge E4.

In some embodiments of the present invention, the first edge E1 and the third edge E3 are in contact with each other and arranged in the same direction, and the second edge E2 and the fourth edge E4 are in contact with each other and arranged in the same direction.

In some embodiments of the present invention, the first pattern 14A and the second pattern 14B partially overlap, and the overlapping portion is defined as a pattern overlapping portion (i.e., the overlapping portion of the conductor pattern 14A and the conductor pattern 14B in the region C).

In some embodiments of the present invention, an optical proximity correction (OPC) step is performed to adjust the critical dimension of the first pattern 14A and the second pattern 14B in the pattern overlapping portion.

In some embodiments of the present invention, the first region A and the second region B partially overlap, and the overlapping range is defined as a double exposure region (that is, the region C).

In some embodiments of the present invention, the ratio of an area of the double exposure region C to an area of the first region A is less than 0.1.

In some embodiments of the present invention, the first pattern 14A and the second pattern 14B are in contact with each other, but the first pattern 14A and the second pattern 14B do not overlap each other (as shown in FIG. 3).

In some embodiments of the present invention, the first region A does not overlap with the second region B, and the first region A is aligned with the second region B (as shown in FIG. 1).

In some embodiments of the present invention, both the first pattern 14A and the second pattern 14B include conductor patterns.

In some embodiments of the present invention, after a first exposure step with a first photomask, a plurality of first device patterns (the device patterns 12 formed in the first region A) are formed on a substrate, and after a second exposure step with a second photomask, a plurality of second device patterns (the device patterns 12 formed in the second region B) are formed on the substrate.

In some embodiments of the present invention, the first device patterns (the device patterns 12 formed in the first region A) and the second device patterns (the device patterns 12 formed in the second region B) are not in contact with each other.

In some embodiments of the present invention, the ratio of the area of the die 10 to the area of the first region A is less than 5.

The invention is characterized in that a splicing pattern is formed on the super-large die by a double exposure method, so as to meet the component size requirements of the super-large die. The difference between the invention and the double exposure in the conventional step is that the formed patterns will be connected with each other and can be spliced into larger or longer patterns. Therefore, device patterns of various sizes can be simply formed on super-large dies without changing the existing process environment.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An exposure method of a semiconductor pattern, comprising:
providing a substrate;
performing a first exposure step with a first photomask to form a first pattern in a first region on the substrate; and
performing a second exposure step with a second photomask to form a second pattern in a second region on the substrate, wherein the first pattern and the second pattern are in contact with each other and aligned with each other at an interface.

2. The exposure method of a semiconductor pattern according to claim 1, further comprising performing a cutting step to cut the substrate into a plurality of dies, wherein the size of each die is larger than an area of the first region, and the first region is equal to a single maximum exposure range of the first photomask.

3. The exposure method of a semiconductor pattern according to claim 2, wherein the areas of the first region And the second region Are equal, and the second region is equal to a single maximum exposure range of the second photomask.

4. The exposure method of a semiconductor pattern according to claim 3, wherein the area of the first region is 26 mm*33 mm.

5. The exposure method of a semiconductor pattern according to claim 3, wherein the size of each die is larger than the area of the first region.

6. The exposure method of a semiconductor pattern according to claim 1, wherein the first pattern comprises a first edge and a second edge, and the second pattern comprises a third edge and a fourth edge.

7. The exposure method of a semiconductor pattern according to claim 1, wherein the first edge and the third edge are in contact with each other and arranged in the same direction, and the second edge and the fourth edge are in contact with each other and arranged in the same direction.

8. The exposure method of a semiconductor pattern according to claim 1, wherein the first pattern and the second pattern partially overlap, and the overlapping range of the first pattern and the second pattern is defined as a pattern overlapping portion.

9. The exposure method of a semiconductor pattern according to claim 8, further comprising an optical correction step of adjusting a critical dimension of the first pattern and the second pattern in the pattern overlapping portion of the pattern.

10. The exposure method of a semiconductor pattern according to claim 8, wherein the first region And the second region partially overlap, and the overlapping range is defined as a double exposure region.

11. The exposure method of a semiconductor pattern according to claim 10, wherein the ratio of an area of the double exposure region to an area of the first region is less than 0.1.

12. The exposure method of a semiconductor pattern according to claim 1, wherein the first pattern and the second pattern are in contact with each other, but the first pattern and the second pattern do not overlap each other.

13. The exposure method of a semiconductor pattern according to claim 12, wherein the first region does not overlap with the second region, and the first region is aligned with the second region.

14. The exposure method of a semiconductor pattern according to claim 1, wherein the first pattern and the second pattern both include a conductor pattern.

15. The exposure method of a semiconductor pattern according to claim 1, wherein after the first exposure step with the first photomask, a plurality of first device patterns are formed on the substrate in the first region, and after the second exposure step with the second photomask, a plurality of second device patterns are formed on the substrate in the second region.

16. The exposure method of a semiconductor pattern according to claim 15, wherein the first device patterns and the second device patterns are not in contact with each other.

17. The exposure method of a semiconductor pattern according to claim 2, wherein a ratio of an area of the die to an area of the first region is less than 5.
